(19) United States
(12) Patent Application Publication
(10) Pub. No.: US 2024/0258199 A1
(43) Pub. Date: Aug. 1, 2024

(54) HEAT DISSIPATION DEVICES

(71) Applicant: THERO NEW MATERIAL TECHNOLOGY CO., LTD, Shenzhen (CN)

(72) Inventors: Xin NIE, Shenzhen (CN); Ruohan YANG, Shenzhen (CN); Yongheng WANG, Shenzhen (CN)

(21) Appl. No.: 18/251,587

(22) Filed: May 3, 2023

Related U.S. Application Data
(63) Continuation of application No. PCT/CN2021/093025, filed on May 11, 2021.

(30) Foreign Application Priority Data
Nov. 3, 2020 (CN) 202011208539.8

(51) Int. Cl. H01L 23/427

(52) U.S. Cl. CPC H01L 23/427

(57) ABSTRACT

A heat dissipation device includes a phase-change accumulator, a water cooler, and a heat conduction cavity. The water cooler comprises a heat absorption mechanism. A top and a bottom of the heat absorption mechanism are fixedly mounted respectively to the phase-change accumulator and the heat conduction cavity. The heat conduction cavity is made of red copper and is attachable to a CPU. The heat conduction cavity is filled with water, and a ratio of a volume of the water within the heat conduction cavity to a volume of the heat conduction cavity is 0.2˜0.9. The phase-change accumulator is filled with a phase-change material.

### CROSS REFERENCE TO RELATED APPLICATIONS

This application is a continuation of International Application No. PCT/CN2021/093025, filed on May 11, 2021, which claims priority to and the benefit of Chinese Patent Application No. 202011208539.8, filed on Nov. 3, 2020. The disclosures of the aforementioned applications are incorporated herein by reference in their entireties.

### TECHNICAL FIELD

The present application relates to electronic temperature control technologies and more particularly, to heat dissipation devices.

### BACKGROUND

A central processing unit (CPU) is one of core electronic components of a computer. With increasing demand for computer capabilities as well as the rapid development of various large-scale software and games, a computing load of the CPU is increasing. Power consumption by the CPU has reached about 80 W. A high-power and high-frequency computer will cause the temperature of CPU to increase, which may shorten a service life of the CPU and degrade performance of the CPU.

A normal operating temperature of the CPU is generally maintained between 45° C.˜55° C. A heat dissipation device in a conventional computer is mainly composed of heat dissipation aluminum and a fan. In use, a power source is used to drive the fan to realize rapid heat dissipation, which results in large electric energy and high power. Importantly, when the heat dissipation device cannot satisfy overheating of the CPU, sometimes the CPU may continue working in an overload state, so that the heat generated by the CPU may cause the temperature of the CPU to exceed a predetermined temperature and the heat dissipation fan cannot quickly take away the heat, which causes the CPU to work at a relatively high temperature, thereby degrading the performance of the CPU and shortening the service life of the CPU.

### SUMMARY

In view of the above, according to one aspect of the present application, there is provided a heat dissipation device. The heat dissipation device includes from top to bottom: a phase-change accumulator, a water cooler, and a heat conduction cavity, wherein the water cooler comprises a heat absorption mechanism, a top and a bottom of a heat absorption mechanism being fixedly mounted respectively to the phase-change accumulator and the heat conduction cavity, and the heat conduction cavity is mounted to a CPU; wherein the heat conduction cavity is filled with water and a ratio of a volume of the water within the heat conduction cavity to a volume of the heat conduction cavity is 0.2˜0.9, and the heat conduction cavity is made of copper; and the phase-change accumulator is filled with a phase-change material.

In one or more embodiments, the phase-change accumulator includes an enclosed energy storage cavity and a first thermal fin, wherein the first thermal fin is arranged in the energy storage cavity and the energy storage cavity is filled with the phase-change material.

In one or more embodiments, the first thermal fin is integrally formed with the energy storage cavity.

In one or more embodiments, the heat absorption mechanism is configured to absorb heat transferred from the heat conduction cavity, and the water cooler further includes a coolant pump and a heat dissipation mechanism. The heat absorption mechanism, the coolant pump, and the heat dissipation mechanism are connected by a hose, and the coolant pump drives water in the heat absorption mechanism and water in the heat dissipation mechanism to circulate.

In one or more embodiments, the heat absorbing mechanism includes a heat transfer cavity and a second thermal fin, wherein the second thermal fin is fixed inside the heat transfer cavity, and the heat transfer cavity is made of red copper and filled with liquid water. The heat absorption mechanism is mainly configured to absorb the heat transferred from the heat conduction cavity.

In one or more embodiments, a temperature sensor is provided in the heat transfer cavity of the heat absorption mechanism. The temperature sensor can measure the heat in the heat absorption mechanism to adjust a gear of a fan in the heat dissipation mechanism.

In one or more embodiments, the heat dissipation mechanism includes a third thermal fin, a metal pipe, and the fan, wherein the metal pipe is filled with liquid water and the fan is configured to release heat from the third thermal fin and the metal pipe into air.

In one or more embodiments, the third thermal fin is a W-shaped thermal fin. The W-shaped thermal fin dissipates heat more rapidly.

In one or more embodiments, the ratio of the volume of the water within the heat conduction cavity to the volume of the heat conduction cavity is 0.4˜0.6, and an air pressure within the heat conduction cavity is less than 1.01×10⁵ Pa.

### BRIEF DESCRIPTION OF THE DRAWINGS

The accompanying drawings, which form a part of the present application, serve to provide a further understanding of the present application and to make other features, objects, and advantages of the present application more apparent. The drawings and description thereof serve to explain the present application and are not to be construed as undue limiting of the present application.

FIG. 1 is a schematic diagram of a structure of a heat dissipation device according to an embodiment of the present application.

FIG. 2 is a schematic diagram of an internal structure of a heat absorption mechanism of the heat dissipation device according to an embodiment of the present application.

FIG. 3 is a schematic diagram of an internal structure of a phase-change accumulator of the heat dissipation device according to an embodiment of the present application.

List of reference numerals in the drawings: 1—phase-change accumulator; 2—water cooler; 3—heat conduction cavity; 4—CPU; 5—energy storage cavity; 6—first thermal fin; 7—heat absorption mechanism; 8—coolant pump; 9—heat dissipation mechanism; 10—hose; 11—heat transfer cavity; 12—second thermal fin; 13—third thermal fin; 14—metal pipe; 15—fan; 16—main board; 17—temperature sensor; 18—power supply; 19—control panel; 20—guide isolation plate.

### DETAILED DESCRIPTION

Some embodiments of the present application will be described in detail below in conjunction with the drawings. The embodiments are described for illustration only and are not intended to limit the present application.

It should be noted that the terms “first”, “second”, and the like in the specification, claims, and the above-mentioned drawing of the present application are used to distinguish similar objects, and are not necessarily used to describe a specific order or a sequence. It is to be understood that the data used in such manner may be interchanged as appropriate, for convenience of describing the embodiments of the present application. Furthermore, the term “including” is intended to cover non-exclusive inclusion.

In the present application, orientations or position relationships indicated by the terms “on” and “under” are based on orientations or position relationships shown in the drawings. These terms are mainly intended to better describe the present application and the embodiments thereof, and are not intended to limit a particular orientation in which indicated devices or components must be oriented.

Also, other than the orientations or the position relationships, a part of the above-mentioned terms may be used to represent other meanings. For example, the term “on” may also be used in some cases to indicate a certain attachment relationship or connection relationship. The person having ordinary skill in the art may understand specific meanings of these terms in the present application according to specific circumstances.

Furthermore, the terms “mounting”, “setting”, “providing”, “connection”, “linking”, and “socketing” are to be understood in a broad sense, which, for example, may be a fixed connection, a detachable connection, or an integral construction, or may be directly connected or indirectly connected through an intermediary, or may be internal connection between two devices, elements, or components. The person having ordinary skill in the art may understand specific meanings of these terms in the present application according to specific circumstances.

It should be noted that the embodiments in the present application and the features in the embodiments may be combined with each other without conflict. The present application will now be described in detail with reference to the accompanying drawings and embodiments.

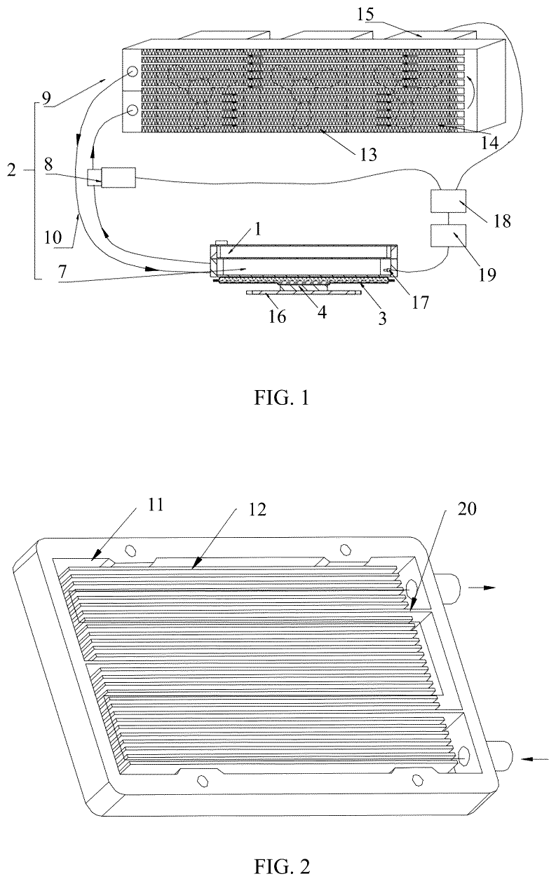

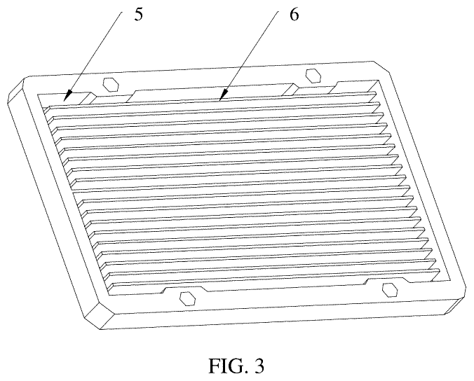

As shown in FIGS. 1-3, the present application relates to a heat dissipation device. The heat dissipation device includes from top to bottom: a phase-change accumulator 1, a water cooler (also referred to as a liquid cooler) 2, and a heat conducting cavity 3. A top and a bottom of a heat absorption mechanism 7 of the water cooler are respectively fixedly mounted (for example, by strong glue attaching) to the phase-change accumulator and the heat conducting cavity, and the heat conducting cavity is mounted to the CPU. The heat conduction cavity is filled with water and a ratio of a volume of the water within the heat conduction cavity to a volume of the heat conduction cavity is 0.2˜0.9. The heat conduction cavity is made of copper. The phase-change accumulator is filled with a phase-change material. The heat conduction cavity transmits heat to the water cooler mainly through liquid water in the heat conduction cavity and a wall of the heat conduction cavity. Between the phase-change accumulator and the heat conduction cavity is mainly the heat absorption mechanism of the water cooler, which dissipates heat through the heat dissipation mechanism of the water cooler after heat absorption. When an overload state occurs to the CPU, the phase-change accumulator starts to function, and the phase-change material in the phase-change accumulator can absorb heat. When the CPU recovers to a normal state, the phase-change material releases heat into the water cooler, and recovers to a normal state, thereby functioning as buffering protection at a peak time of the CPU in the overload state. The heat conduction cavity is filled with the water and the ratio of the volume of the water within the heat conduction cavity to the volume of the heat conduction cavity is 0.2˜0.5. That is, there is liquid water and an air layer in the heat conduction cavity. After the liquid water is evaporated, heat is transmitted to the water cooler through water vapor, so that efficiency is higher. The heat conduction cavity is made of red copper. The red copper has good heat conductivity, is not easy to rust, has long usage time, and has good durability. The CPU is mounted on a main board 16.

As shown in FIGS. 1-3, the phase-change accumulator includes an enclosed energy storage cavity 5 and a first thermal fin 6. The first thermal fin is arranged in the energy storage cavity and the phase-change material is filled in the energy storage cavity. The first thermal fin is integrally formed with the energy storage cavity.

In one or more embodiments, the phase-change material in the phase-change accumulator adopts a phase-change material having a phase-change point within 56˜75° C., and further in one or more embodiments a phase-change material having a phase-change point within 56˜65° C. Of course, in the present disclosure, the phase-change material is selected according to a CPU normal temperature and a CPU limit temperature. Generally, the phase-change point of the phase-change material is 5˜10° C. higher than the CPU normal operating temperature. A regular CPU normal operation temperature is 45˜55° C. Therefore, the phase-change material having the phase-change point within 56˜65° C. is selected. For example, a phase-change point of the phase-change material in the phase-change accumulator is 59° C. The phase-change material having the phase-change point of 59° C. ensures a normal and efficient operation of the CPU. When the phase-change point exceeds 59° C., the phase-change accumulator functions.

As shown in FIGS. 1-3, the water cooler includes the heat absorption mechanism 7, a coolant pump 8, and a heat dissipation mechanism 9. The heat absorption mechanism is configured to absorb heat transferred from the heat conducting cavity. The heat absorption mechanism, the coolant pump, and the heat dissipation mechanism are connected by a hose 10. The coolant pump drives water in the heat absorption mechanism and water in the heat dissipation mechanism to circulate. The coolant pump 8 is electrically connected to a power supply 18. The power supply is electrically connected to a control panel 19. The control panel is configured to control a gear of the fan and a switch of the coolant pump. A temperature sensor 17 is electrically connected to the control panel. The control panel is electrically connected to the power supply.

As shown in FIG. 2, the heat absorption mechanism includes a heat transfer cavity 11 and a second thermal fin 12. The second thermal fin is fixed inside the heat transfer cavity, liquid water is filled in the heat transfer cavity, and the heat transfer cavity is made of red copper. The heat absorption mechanism is mainly configured to absorb the heat transferred from the heat conduction cavity. Also provided in FIG. 2 are two guide isolation plates 20, a length of which is smaller than a length of the second thermal fin. A main function of the guide isolation plates is liquid water backflow.

A temperature sensor may be provided in the heat transfer cavity of the heat absorption mechanism. The temperature sensor can measure heat in the heat absorption mechanism to adjust a gear of a fan in the heat dissipation mechanism through the control panel. The temperature sensor is electrically connected to the control panel. When the temperature sensor exceeds the normal temperature, the gear of the fan is adjusted to accelerate an operation of the fan and improve heat dissipation capability.

As shown in FIGS. 1-3, the heat dissipation mechanism includes a third thermal fin 13, a metal pipe 14, a fan 15, and the control panel. The control panel is a miniature controller. Liquid water is filled in the metal pipe. The fan releases heat from the third thermal fin and the metal pipe into the air. The third thermal fin is a “W-shaped” heat dissipation device. The W-shaped thermal fin dissipates heat more rapidly.

In one or more embodiments, the ratio of the volume of the water within the heat conduction cavity to the volume of the heat conduction cavity is 0.4˜0.6, and an air pressure within the heat conduction cavity is less than 1.01×10⁵ Pa. As shown in FIG. 1, an air pressure within the heat conduction cavity is smaller than 0.8×10⁵ Pa. That is, the air in the heat conduction cavity is pumped to a low pressure, which is less than the standard atmospheric pressure, thereby reducing a temperature at which the liquid water vaporizes. In a heat transfer process, the water in the heat conduction cavity continuously vaporizes and liquefies, and continuously absorbs and releases heat, thereby improving overall heat dissipation and heat conduction efficiency.

A basic working process of the heat dissipation device is: when a CPU temperature increases, transferring heat to the water cooler through the liquid water and water vapor in the heat conduction cavity, and dissipating the heat through the water cooler. Under the circumstances that the temperature exceeds heat dissipation capacity of the water cooler, when the CPU is in the overload state and the temperature exceeds the phase-change point of the phase-change material in the phase-change accumulator, the phase-change accumulator starts to work and the phase-change material liquefies, thereby rapidly absorbing a large amount of heat and preventing the water cooler from heating up. When the CPU returns to a normal load, the water cooler also returns to a normal temperature region below the phase-change point. As the temperature decreases, the liquefied phase-change material releases heat to re-solidify, returns the heat absorbed at the peak time to the water cooler, and dissipates heat in the air through the heat dissipation mechanism of the water cooler. In this process, the phase-change material absorbs or releases a part of the heat through phase change to prevent the CPU temperature from rising, thereby protecting a stable operation of a system.

This embodiment utilizes a three-layer structure of the phase-change accumulator, the water cooler, and the heat conduction cavity. A function of the phase-change accumulator reduces the CPU temperature when the CPU is in an overloaded state, thereby allowing the CPU to work normally at a normal temperature. This solves a technical problem that a computer cannot be used normally because a CPU in the computer cannot rapidly dissipate heat in an overload state which degrades performance of the CPU and shorten a service life of the CPU.

Some embodiments of the present application have been described above and are not intended to limit the present application. Various modifications and variations may occur to those skilled in the art. Any modifications, equivalents, variations, etc. within the spirit and principles of the present application are intended to fall within the scope of the present application.

What is claimed is:

1. A heat dissipation device, comprising a phase-change accumulator, a water cooler, and a heat conduction cavity,
wherein the water cooler comprises a heat absorption mechanism, a top and a bottom of the heat absorption mechanism being fixedly mounted respectively to the phase-change accumulator and the heat conduction cavity;
the heat conduction cavity is made of red copper and is attachable to a CPU, and the heat conduction cavity is filled with water, a ratio of a volume of the water within the heat conduction cavity to a volume of the heat conduction cavity being 0.2˜0.9; and
the phase-change accumulator is filled with a phase-change material.

2. The heat dissipation device of claim 1, wherein the phase-change accumulator comprises an enclosed energy storage cavity and a first thermal fin arranged in the energy storage cavity, and the energy storage cavity is filled with the phase-change material.

3. The heat dissipation device of claim 2, wherein the first thermal fin is integrally formed with the energy storage cavity.

4. The heat dissipation device of claim 1, wherein:
the heat absorption mechanism is configured to absorb heat transferred by the heat conduction cavity;
the water cooler further comprises a coolant pump and a heat dissipation mechanism, and the heat absorption mechanism, the coolant pump, and the heat dissipation mechanism are connected by a hose; and
the coolant pump is configured to drive water in the heat absorption mechanism and water in the heat dissipation mechanism to circulate.

5. The heat dissipation device of claim 4, wherein the heat absorption mechanism comprises a heat transfer cavity and a second thermal fin fixed inside the heat transfer cavity, and the heat transfer cavity is made of red copper and filled with liquid water.

6. The heat dissipation device of claim 5, wherein a temperature sensor is provided in the heat transfer cavity of the heat absorption mechanism.

7. The heat dissipation device of claim 4, wherein the heat dissipation mechanism comprises a third thermal fin, a metal pipe, and a fan;
the metal pipe is filled with liquid water; and
the fan is configured to release heat from the third thermal fin and the metal pipe into air.

8. The heat dissipation device of claim 7, wherein the third thermal fin is a W-shaped thermal fin.

9. The heat dissipation device of claim 1, wherein the ratio is 0.4˜0.6, and an air pressure within the heat conduction cavity is less than 1.01×10⁵ Pa.
